(19) United States
(12) Patent Application Publication
(10) Pub. No.: US 2026/0239901 A1
(43) Pub. Date: Aug. 13, 2026

(54) DIE STRESS MODULATION FOR IMPROVED DEVICE LAYER STACKING

(71) Applicant: Applied Materials, Inc., Santa Clara, CA (US)

(72) Inventors: Sony Varghese, Manchester, MA (US); Anil Uttam Mane, Lexington, MA (US); Yan Zhang, Westford, MA (US); Yin Wei Lim, Singapore (SG); Guan Huei See, Singapore (SG)

(73) Assignee: Applied Materials, Inc., Santa Clara, CA (US)

(21) Appl. No.: 19/223,880

(22) Filed: May 30, 2025

Related U.S. Application Data
(60) Provisional application No. 63/757,996, filed on Feb. 13, 2025.

(51) Int. Cl. H01L 21/265; H01J 37/305; H01J 37/317; H01L 21/66

(52) U.S. Cl. CPC H10P 30/204; H01J 37/3053; H01J 37/3171; H10P 30/208; H10P 74/203

(57) ABSTRACT

Embodiments herein are directed to localized die distortion correction. In some embodiments, a method includes performing a metrology scan of a substrate, wherein the metrology scan determines a die warp or a die bow for each die of a plurality of dies across the substrate. The method further includes directing first ions to the substrate, wherein the first ions are directed to a first die at a first dose and a first energy, and wherein the first dose and the first energy are determined based on the die warp or the die bow of the first die. The method further includes directing second ions to the substrate, wherein the second ions are directed to a second die at a second dose and a second energy, and wherein the second dose and the second energy are determined based on the die warp or the die bow of the second die.

### RELATED APPLICATION

This application claims priority to U.S. provisional patent application Ser. No. 63/757,996, filed on Feb. 13, 2025, entitled “Die Stress Modulation for Improved Device Layer Stacking,” which is incorporated herein by reference in its entirety.

### FIELD

The disclosure relates to substrate processing and, more particularly, to die stress modulation for improved device layer stacking.

### BACKGROUND

Devices such as integrated circuits, memory devices, and logic devices may be fabricated on a substrate such as a silicon, silicon carbide, or other semiconductor wafer by a combination of deposition processes, etching, ion implantation, annealing, and other processes. Generally, certain requirements are established for the flatness and thickness uniformity of the wafers. Fabrication processes result in varied stress and strain across the wafer, resulting in variations in wafer bow. Such variations may lead to errors in downstream processes, for example, during lithographic patterning, device layer stacking, epitaxial formation, metal and dielectric filling or the like.

In addition to wafer level errors, once the wafers are thinned, diced and subsequently attached to a substrate, which may be made from polymeric materials, silicon or glass, stresses in the die can result in poor stacking quality. Poor stacking quality is manifested as insufficient electrical contact resulting in open circuits in high areas or short circuits in lower areas due to higher than desired deformation of electrical contacts. Some stacked dies can show both issues, especially when there are complex stress regimes within the constituent dies.

It is with respect to these and other considerations the present embodiments are provided.

### SUMMARY OF THE DISCLOSURE

This Summary is provided to introduce a selection of concepts in a simplified form further described below in the Detailed Description. This Summary is not intended to identify key features or essential features of the claimed subject matter, nor is the summary intended as an aid in determining the scope of the claimed subject matter.

In one embodiment, a method may include a method may include performing a metrology scan of a substrate, wherein the metrology scan determines a die warp or a die bow for each die of a plurality of dies across the substrate. The method may further include directing first ions to the substrate, wherein the first ions are directed to a first die of the plurality of dies at a first dose and a first energy, and wherein the first dose and the first energy are determined based on the die warp or the die bow of the first die. The method may further include directing second ions to the substrate, wherein the second ions are directed to a second die of the plurality of dies at a second dose and a second energy, and wherein the second dose and the second energy are determined based on the die warp or the die bow of the second die.

In another embodiment, an ion implanter may include an ion source for generating an ion beam, an end station comprising a platen for supporting a substrate to be implanted by the ion beam, and a main controller operatively coupled to the ion source. The main controller is adapted to receive an output from a metrology scan of the substrate, wherein the metrology scan determines a die warp or a die bow for each die of a plurality of dies across the substrate. The main controller may be further adapted to direct first ions to a first die of the plurality of dies at a first dose and a first energy, wherein the first dose and the first energy are determined based on the die warp or the die bow of the first die. The main controller may be further adapted to direct second ions to a second die of the plurality of dies at a second dose and a second energy, and wherein the second dose and the second energy are determined based on the die warp or the die bow of the second die.

In another embodiment, a method of implanting wafer dies to mitigate die deformations, may include receiving an output from a metrology scan of the substrate, wherein the metrology scan determines a die warp or a die bow for each die of a plurality of dies across the substrate. The method may further include directing first ions to a first die of the plurality of dies at a first dose and a first energy, wherein the first dose and the first energy are determined based on the following: the die warp or the die bow of the first die, a first thickness of the first die, and a species of the first ions. The method may further include directing second ions to a second die of the plurality of dies at a second dose and a second energy, and wherein the second dose and the second energy are determined based on the following: the die warp or the die bow of the second die, a second thickness of the second die, and a species of the second ions.

### BRIEF DESCRIPTION OF THE DRAWINGS

The accompanying drawings illustrate exemplary approaches of the disclosure, including the practical application of the principles thereof, as follows:

FIG. 1 depicts a side cross-sectional view of a substrate during a metrology scan, according to embodiments of the present disclosure;

FIG. 2 depicts a side cross-sectional view of the substrate following a wafer bonding process, according to embodiments of the present disclosure;

FIG. 3 depicts a side cross-sectional view of the substrate following a wafer thinning process, according to embodiments of the present disclosure;

FIG. 4 depicts a side cross-sectional view of the substrate following an etch back process, according to embodiments of the present disclosure;

FIG. 5 depicts a side cross-sectional view of the substrate during an ion treatment, according to embodiments of the present disclosure;

FIG. 6 depicts a side cross-sectional view of the substrate following passivation and under bump metallization processes, according to embodiments of the present disclosure;

FIG. 7 is a schematic view illustrating an exemplary embodiment of a beam-line ion implanter, according to embodiments of the present disclosure;

FIG. 8 is a top view of an example dose map for a plurality of dies of a substrate, according to embodiments of the present disclosure;

FIGS. 9A-9D are top views of example stress neutralizing patterns on a die of a substrate, according to embodiments of the present disclosure;

FIG. 10A is a top view and FIG. 10B is a side cross-sectional view of a semiconductor substrate, according to embodiments of the present disclosure;

FIG. 11 depicts a side cross-sectional view of the substrate during an ion treatment, according to embodiments of the present disclosure;

FIG. 12 depicts a side cross-sectional view of the substrate following the ion treatment, according to embodiments of the present disclosure;

FIG. 13 depicts a side cross-sectional view of a substrate during an angled ion treatment, according to embodiments of the present disclosure;

FIG. 14 depicts a side cross-sectional view of a substrate during an ion treatment, according to embodiments of the present disclosure; and

FIGS. 15A-15E depict atomic lattice structures for different silicon carbide polytypes according to embodiments of the present disclosure.

The drawings are not necessarily to scale. The drawings are merely representations, not intended to portray specific parameters of the disclosure. The drawings are intended to depict exemplary embodiments of the disclosure, and therefore are not to be considered as limiting in scope. In the drawings, like numbering represents like elements.

Furthermore, certain elements in some of the figures may be omitted, or illustrated not-to-scale, for illustrative clarity. The cross-sectional views may be in the form of “slices”, or “near-sighted” cross-sectional views, omitting certain background lines otherwise visible in a “true” cross-sectional view, for illustrative clarity. Furthermore, for clarity, some reference numbers may be omitted in certain drawings.

### DETAILED DESCRIPTION

The present embodiments will now be described more fully hereinafter with reference to the accompanying drawings, where some embodiments are shown. The subject matter of the present disclosure may be embodied in many different forms and are not to be construed as limited to the embodiments set forth herein. These embodiments are provided so the disclosure will be thorough and complete, and will fully convey the scope of the subject matter to those skilled in the art.

Provided herein are approaches for mitigating distortions and curvature (e.g., wafer or die warp and/or bowing) in dies of silicon and silicon carbide substrates using an ion implant process. The ion implant may generate a compensating stress, where the compensating stress may operate to reduce these distortions and/or curvatures in the wafer dies. In some approaches, an incoming silicon or silicon carbide substrate is measured (e.g., scanned) to determine properties of the substrate, such as thickness, bow, and warpage, and stress at each of a plurality of locations. Based on these detected properties, implant conditions are generated for a subsequent ion implant to the substrate, wherein the ion implant may include varied implant conditions for different locations across the substrate. In some embodiments, the implant conditions may also be generated based on simulations or previous modeling. The implant conditions may include dose, energy, species type, temperature, angle of implant delivery, channeling method etc. As a result of the implant, local stress in the substrate can be modified to address the die warp and/or die bowing. In some approaches, the ion implant is performed directly to the substrate, as opposed to a film layer formed over the substrate, thus minimizing the complexity of the fabrication flow.

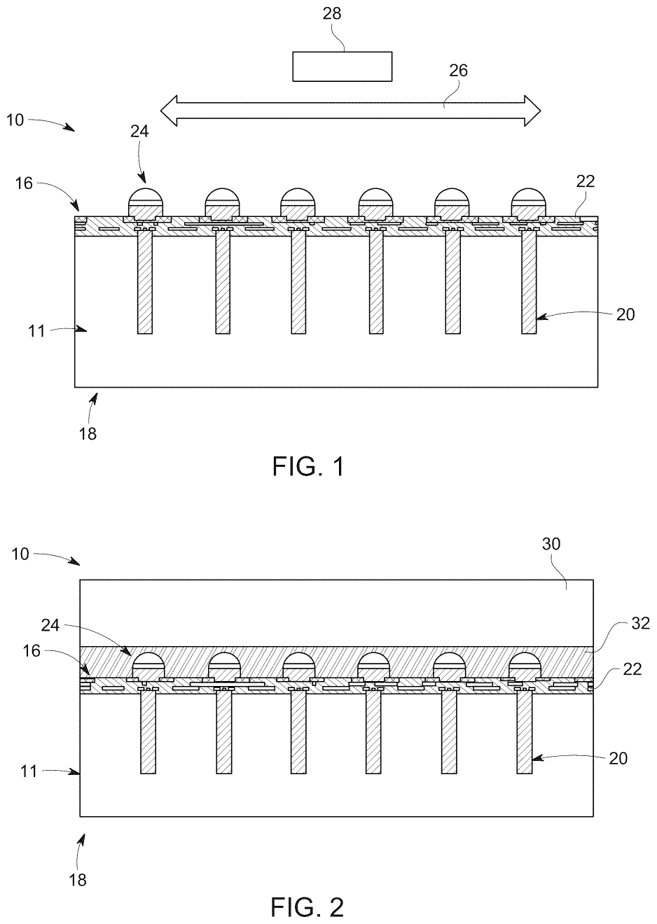

FIG. 1 depicts a side cross-sectional view of a portion of a device 10 according to embodiments of the present disclosure. The device 10 may include a fully fabricated device wafer or substrate 11 having a front side 16 and a back side 18. The substrate 11 may be a silicon substrate (e.g., single crystal silicon), a silicon carbide (SiC) substrate, or other material. Although non-limiting, the device 10 may be a 3D stacked memory device, such as a 3D through-silicon via (TSV) dynamic random-access memory (DRAM), including a plurality of vias 20 formed therein. The device 10 may further include an under-bump metallization (UBM) layer 22 and a micro bump 24 formed over each of the vias 20.

As further shown in FIG. 1, the device 10 may be premeasured/s-26 to determine properties of the substrate 11, such as thickness, bow, warp, stress, deformation, defects etc., at each of a plurality of locations across the substrate 11. More specifically, a metrology scan may be performed along the front side 16 and/or back side 18 to measure wafer bow and wafer warp at a plurality of locations. In some embodiments, the metrology scan may be performed by metrology tool 28 operable to measure parameters across the device 10 at a plurality of orientations (e.g., 5-10 orientations). The metrology tool 28 may be further operable to map the plurality of locations, which may be arranged uniformly or non-uniformly across the device, and to correlate the parameters to each of the plurality of locations. When the arrangement is consistent or uniform, the plurality of locations may be identifiable according to a grid or coordinate system. The parameters from the plurality of locations are used to generate an ion implant recipe, as will be described in greater detail below. In various embodiments, the metrology scan may be performed multiple times and/or at different times of the device processing. For example, the metrology scan may be performed before or after formation of the UBM layer 22 and the micro bumps 24.

As shown in FIG. 2, a bonding layer 30 may then be formed over the device 10, including over the UBM layer 22 and the micro bumps 24. In some embodiments, the bonding layer 30 is a temporary silicon layer secured to the device 10 by an adhesive 32. In some embodiments the wafer may permanently bonded by oxide bonding or hybrid bonding to the boding layer 30. In other embodiments, the bonding layer 30 may be stack of dies attached to another carrier that may have been constructed by the using a die to wafer stacking process.

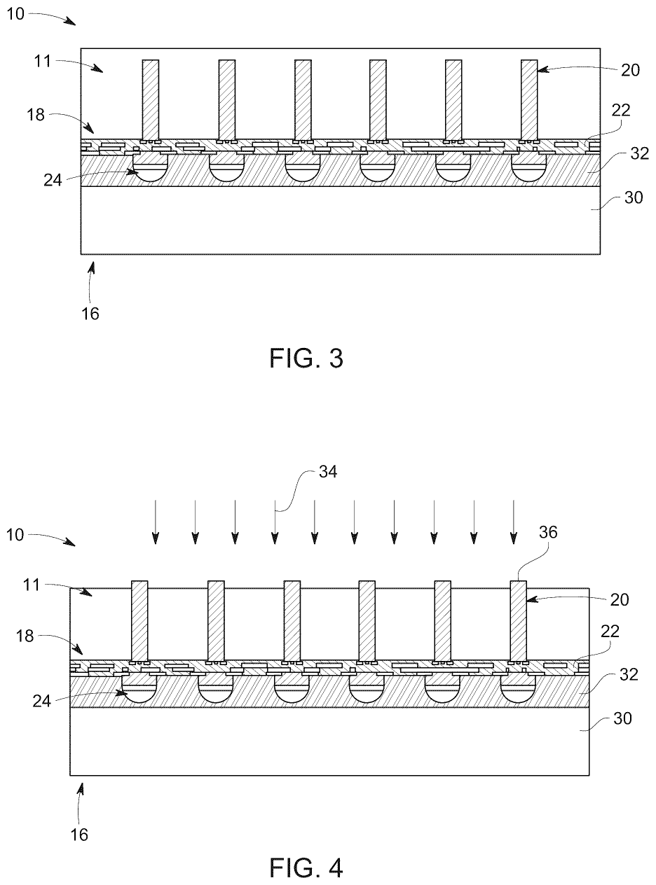

As shown in FIG. 3, the device 10 may be flipped and then thinned, e.g., by removing a portion of the substrate 11. Although non-limiting, the substrate 11 may be thinned using a chemical mechanical planarization (CMP) process, which generally stops above the vias 20. An etch back process 34 may be performed, as shown in FIG. 4, to partially expose an end 36 of each of the vias 20. In some embodiments, the vias 20 may be exposed by a grind or CMP process as well. As wafer thickness reduces, effect of inherent stressesis reduced, stress in the wafer increases and hence wafer warpage increases.

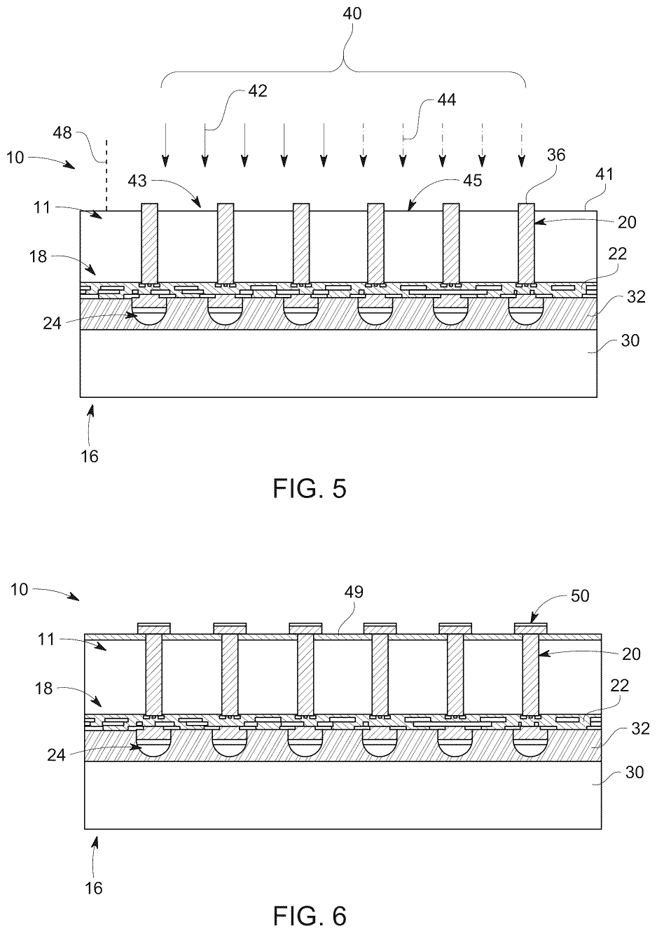

As shown in FIG. 5, to address the wafer warpage, an ion treatment 40 may then be performed to deliver ions into the substate 11. Advantageously, the ion treatment 40 is performed directly to an exposed surface 41 of the substrate 11, without the use of an additional deposited film layer, such as a stress compensation film such as Si3N4 and SiO2. In various embodiments, the ion treatment can be performed in the range of temperatures (e.g. −100 C to 600 C) depending on temperature limitations of UBM layer 22 as well as the other layers or features of the device 10. The ion treatment 40 may include one or more ion implants (e.g., scanned spot beam implant or ribbon ion beam implant), which may impact all of the substrate 11, but which may be delivered with a different dose and/or implant energy to different areas of the substrate 11, e.g., based on the results of the metrology scan and known parameters of the substrate 11 and/or process (e.g., original substrate thickness, target thickness of the substrate following a thinning process, measured thickness of substrate following the thinning process, substrate crystallographic orientation, die stacking temperature, etc.). For example, first ions 42 may be directed to a first location 43 with a first dose and a first ion implant energy, while second ions 44 may be directed to a second location 45 with a second dose and a second ion implant energy. The first location 43 and the second location 45 may correspond to specific dies, or groupings of dies, of the substrate 11.

In some embodiments, the first dose and the first energy may be determined using an algorithm that incorporates a thickness of the substrate 11 and a first wafer/bow measurement value at the first location 43. Similarly, the second dose and the second energy may be determined using the thickness of the substrate 11 and a second wafer/bow measurement value at the second location 45. In some embodiments, the thickness of the substrate 11 and a second wafer/bow measurement may incorporate warping information not just locally at the first and second locations 43, 45 but from surrounding regions as well.

In one non-limiting example, the second location 45 may have a greater warp or bow than in the first location 43. As such, the second ions 44 may be delivered with a relatively higher dose and/or implant energy than the first ions 42. In some embodiments, the dose may be between 1e12 and 1e16 atom/cm2, while the energy range can be 50-500 keV. Alternatively, in the case of a proton ion beam, the energy range may be greater than 1 MeV.

In various embodiments, the species of the first ions 42 and the second ions 44 of the ion treatment 40 may be the same or different. For example, the first and second ions 42, 44 may include one or more neutral ion species, such as silicon, argon, nitrogen, germanium, or carbon, which are directed to the substrate 11 vertically or at a non-zero angle relative to a perpendicular 48 extending from a plane defined by the exposed surface 41 of the substrate 11.

In still other embodiments, ions of the ion treatment 40 may be directed to the substrate 11 using a channeling implant to further modulate strains. For example, ions may be directed at a non-zero angle, e.g., <20° relative to the perpendicular 48 to enable a deeper implant penetration.

As a result of the ion treatment 40, die warp and/or die bowing can be locally mitigated for each of a plurality of locations.

In some embodiments, one or more further metrology scans of the substrate 11 may be performed by the metrology tool 28 (FIG. 1), e.g., following the ion treatment 40 and/or following the thinning of the substrate 11, to determine an updated die warp and/or an updated die bow at each of the plurality of locations along the substrate 11. This information can be fed back into the algorithm for determining future implant parameters.

Following the ion treatment 40, processing of the device 10 may continue, as shown in FIG. 6. For example, a dielectric 49 may be deposited over the substrate 11 following the ion treatment 40, and a conductive pad 50 may then be formed atop each of the vias 20. In some embodiments, any additional stress contributions to the device from the dielectric 49 and conductive pad 50 may be feedback to the algorithm to account for potential change bow after these processes are completed. Although not shown, the bonding layer 30 may then be removed, and the device 10 may be stacked with other layers, as is known.

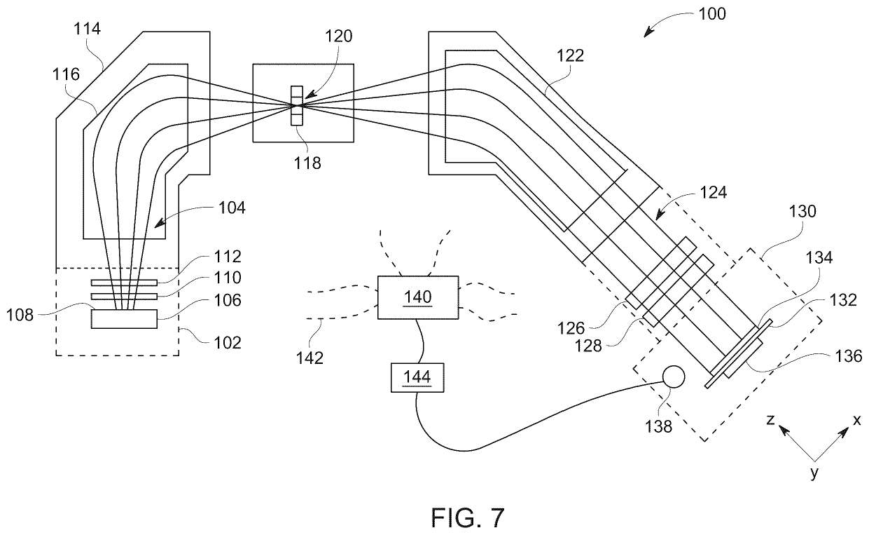

The devices and methods disclosed herein are described in connection with an ion implanter used in the processing of workpieces such as, for example, semiconductor substrate 11. FIG. 7 is a schematic diagram illustrating an exemplary beam-line ion implanter 100 operable to perform the processes shown in FIGS. 1-6 and described herein. The beam-line ion implanter 100 is one of many examples of beam-line ion implanters capable of producing and directing ions for processing workpieces.

In general, the beam-line ion implanter 100 (hereinafter “the implanter 100”) may include an ion source 102 adapted to generate ions for forming an ion beam 104. The ion source 102 may include an ion chamber 106 where the ions are produced. The ion species may be, or may include or contain, hydrogen, helium, carbon, neon, oxygen, nitrogen, arsenic, boron, phosphorus, aluminum, indium, gallium, antimony, carborane, other rare gases, alkanes, another large molecular compound, or other p-type or n-type dopants. The present disclosure is not limited in this regard. The generated ions may be extracted from the ion chamber 106 by a series of extraction electrodes to form the ion beam 104. In particular, the ions may be extracted from chamber 106 by an extraction electrode 108 (e.g., integral with an exit aperture of the ion chamber 106), a suppression electrode 110, and a ground electrode 112.

The ion beam 104 is mass analyzed by mass analyzer 114 having a resolving magnet 116 and a masking electrode 118 having a resolving aperture 120. The resolving magnet 116 deflects ions in the ion beam 104 to isolate ions having a desired mass-to-charge ratio associated with a particular dopant ion species, which are subsequently allowed to pass through the resolving aperture 120. Undesired ion species are deflected into, and blocked, by the masking electrode 118 and thus do not pass through the resolving aperture 120.

Ions of the desired ion species pass through resolving aperture 120 to an angle corrector magnet 122. The angle corrector magnet 122 deflects ions of the desired ion species and converts the ion beam from a diverging ion beam to a focused ion beam 124 (e.g., a ribbon beam or a spot beam) having generally parallel ion trajectories. The implanter 100 may further include acceleration unit 126 and/or a deceleration unit 128. The acceleration and deceleration units 126, 128 may be used to speed up or slow down the focused ion beam 124. Speed adjustment is accomplished by applying specific combinations of voltage potentials to sets of electrodes disposed on opposite sides of the focused ion beam 124. As the focused ion beam 124 passes between the electrodes, ion energies are increased or decreased depending on the applied voltage potentials. Since the depth of an ion implant is proportional to the energy and dose of the impinging ion beam, beam acceleration may be desirable when performing deep ion implants. Conversely, where shallow ion implants are desired, beam deceleration is performed to ensure the impinging ions travel only a short distance into the workpiece.

An end station 130 of the implanter 100 may include a platen 132 configured to support one or more workpieces, such as substrate 134, which may be the same or similar to substrate 11 described herein. The substrate 134 may be disposed in the path of the focused ion beam 124 and ions of the desired ion species may be implanted into the substrate 134. The substrate 134 may be, for example, a semiconductor wafer. The end station 130 may include a scanner 136 adapted to move the platen 132 and the substrate 134 perpendicular to the long dimension of the focused ion beam 124 (i.e., along the X-axis and the Y-axis of the illustrated Cartesian coordinate system) for distributing ions over the entire surface of the substrate 134. The scanner 136 may further be adapted to move the platen 132 and the substrate 134 parallel to the long dimension of the focused ion beam 124 (i.e., along the Y-axis of the illustrated Cartesian coordinate system). The scanner 136 may further be adapted to tilt or rotate the platen 132 and the substrate 134 relative to the focused ion beam 124 (e.g., rotate the platen 132 and the substrate 134 about the Y-axis of the illustrated Cartesian coordinate system). The present disclosure is not limited in this regard. The implanter 100 may include additional components known to those skilled in the art and may incorporate hot or cold implantation of ions in some embodiments.

For example, in some embodiments, the platen 132 may be heated using an external or embedded heating element, such as a resistive heater, or may be heated using radiant heat, such as heating lamps disposed above or below the platen 132. In other embodiments, the heating element may additionally, or alternatively, be located in a load lock chamber or a separate pre-heat chamber to pre-heat the substrate 134 before it reaches the platen 132. Even with a pre-heat, the platen 132 may include the internal heating element.

The implanter 100 may further include one or more metrology components 138. The metrology components 138 may include, and are not limited to, an ellipsometer, a reflectometer, a pyrometer, an X-ray diffractometer, etc. The metrology components 138 may facilitate the analysis/measurement of various aspects, features, and characteristics of the substrate 134 before, during, or after ion beam processing is performed. For example, the metrology components 138 may be used to analyze the substrate 134 prior to processing to determine one or more dimensional aspects, e.g., warpage, bowing, average thickness, thickness variation. In another example, the metrology components 138 may be used to analyze/measure the depth, profile, quality, etc., of an implantation after processing. The present disclosure is not limited in this regard.

The implanter 100 may further include a main controller 140 operatively coupled to one or more of the ion source 102, the mass analyzer 114, the angle corrector magnet 122, the acceleration unit 126, the deceleration unit 128, the scanner 136, the metrology components 138, etc., by various data lines (as indicated by the dashed lines 142) for controlling and coordinating the operation of the aforementioned components. The main controller 140 may include a processor, such as a known type of microprocessor, dedicated semiconductor processor chip, general purpose semiconductor processor chip, or similar device. The main controller 140 may further include a memory or memory unit coupled to the processor, where the memory unit contains a control routine for controlling the operation of the components of the implanter 100 in a predetermined manner based on various inputs as further described below.

The memory unit of the main controller 140 may comprise an article of manufacture. In one embodiment, the memory unit may comprise any non-transitory computer readable medium or machine-readable medium, such as an optical, magnetic or semiconductor storage. The storage medium may store various types of computer executable instructions to implement one or more of logic flows described herein. Examples of a computer readable or machine-readable storage medium may include any tangible media capable of storing electronic data, including volatile memory or non-volatile memory, removable or non-removable memory, erasable or non-erasable memory, writeable or re-writeable memory, and so forth. Examples of computer executable instructions may include any suitable type of code, such as source code, compiled code, interpreted code, executable code, static code, dynamic code, object-oriented code, visual code, and the like. The embodiments are not limited in this context.

The implanter 100 may further include a feedforward controller 144 operatively coupled to the metrology components 138 and to the main controller 140. As described in greater detail below, the feedforward controller 144 may be adapted to receive and process information from the metrology components 138 and to influence the main controller 140 to operate various components of the implanter 100 to improve the implantation processes performed by the implanter 100. For example, prior to implantation of the substrate 134, the feedforward controller 144 may receive X-ray diffraction measurements of the substrate 134 from the metrology components 138 and may use such measurements to determine wafer warpage and bowing at various locations of the substrate 134.

The feedforward controller 144 may use the dimensional data to determine a subsequent ion implant using a predictive model, wherein data relating to the performance of the implanter 100, as determined by measurements taken after previous implantation processes, may be used to adjust the dose, energy, species, etc., of the ion implant to compensate for unintended thickness variations or wafer bow and stress across the substrate 134.

Like the main controller 140, the feedforward controller 144 may include a processor, such as a known type of microprocessor, dedicated semiconductor processor chip, general purpose semiconductor processor chip, or similar device. The feedforward controller 144 may further include a memory or memory unit coupled to the processor. The memory unit of the feedforward controller 144 may comprise an article of manufacture. In one embodiment, the memory unit may comprise any non-transitory computer readable medium or machine readable medium, such as an optical, magnetic or semiconductor storage. The storage medium may store various types of computer executable instructions to implement one or more of logic flows described herein (e.g., the predictive model described below). Examples of a computer readable or machine-readable storage medium may include any tangible media capable of storing electronic data, including volatile memory or non-volatile memory, removable or non-removable memory, erasable or non-erasable memory, writeable or re-writeable memory, and so forth. Examples of computer executable instructions may include any suitable type of code, such as source code, compiled code, interpreted code, executable code, static code, dynamic code, object-oriented code, visual code, and the like. The embodiments are not limited in this context.

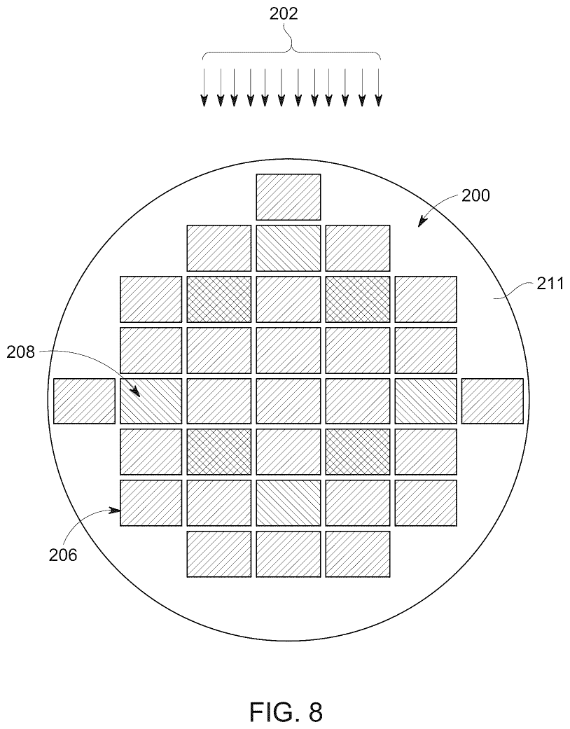

FIG. 8 is a top view of a dose map 200 for an example substrate 211, which may be the same or similar to substrate 11 described herein. The dose map 200 may be characterized by a plurality of coordinates and dimensional information corresponding to the plurality of coordinates. As discussed above, the incoming substrate may be subject to a metrology scan 202, which may record dimensional data related to bowing and warpage for a plurality of areas across the substrate 211. These areas may correspond to a single die or group of dies. In some embodiments, the scan 202 may be part of a metrology routine. The dose map 200 may then be generated, which may be two-dimensional (2-D), to identify those areas 206 of the substrate 211 requiring a higher dose and those areas 208 of the substrate requiring a lower dose. In general, areas 206 requiring a higher dose correlate to portions of the substrate 211 with greater distortion, while areas 208 requiring a lower dose correlate to portions of the substrate 211 with less distortion.

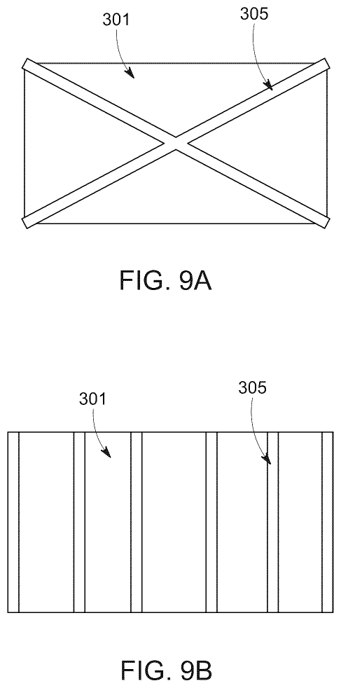

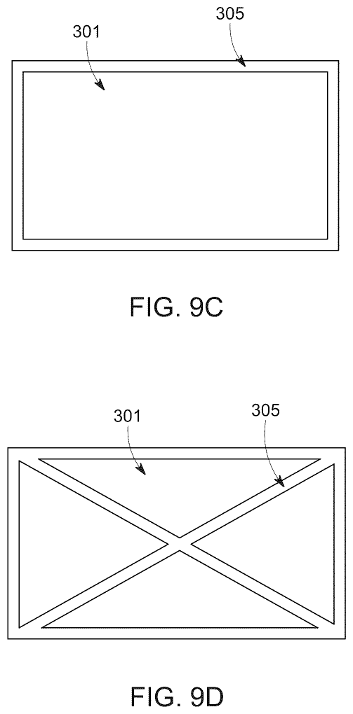

As shown in FIGS. 9A-9D , in some embodiments, the implant procedure can implant varied shapes or patterns 305 on a die 301 of a substrate, e.g., with as high as 40:1 dose ratio, or greater. Nonuniform patterns implanted across the die are selected to neutralize the stress and corresponding bow/warp, which may in some cases be achieved by making the die 301 more rigid and therefore less susceptible to distortion. The process of implanting in single crystal materials, such as silicon or silicon carbide, can result in the distortion of the crystal lattice by generation of defects, clustering of defects, localized rearrangement or atoms in non-crystallographic clusters, often referred to as amorphization and by filling in volume between atoms in the crystal structure by the implanted atom. Die size can be varied with respect applications. For example, logic dies are larger in size compare DRAM memory dies. The patterns 305 can be modelled using Finite Element Analysis (FEA), and can be patterned onto the substrate either using either spot beam control or by using conventional lithography methods.

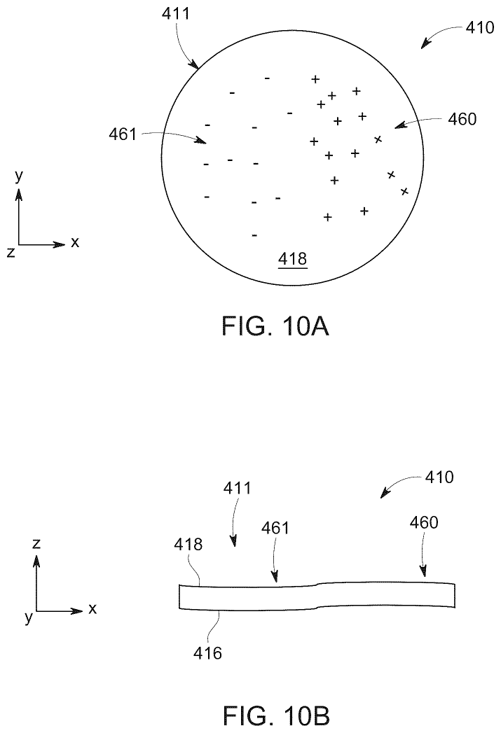

FIG. 10A is a top view and FIG. 10B is a side view of another device 410 according to embodiments of the present disclosure. The device 410 may include a wafer or substrate 411 having a front side 416 and a back side 418. In this embodiment, the substrate 411 may be a SiC substrate including areas of distortion, such as bowing or warp in a first section 460 and a second section 461 of the substrate 411, wherein the first section 460 and the second section 461 may each correspond to specific dies, or groupings of dies, of the substrate 411. The bowing/curvature of the first section 460 in the positive z-direction is represented by the (+) symbols, while the bowing/curvature in the second section 461 in the negative z-direction is represented by the (−) symbols. Bow shape can be concave, convex or mixed.

A metrology scan may be performed along the front side 416 and/or back side 418 to measure wafer thickness, as well as wafer bow and/or wafer warp at a plurality of locations, such as at the first section 460 and the second section 461. In some embodiments, the metrology scan may be performed by the metrology tool 28, as described above.

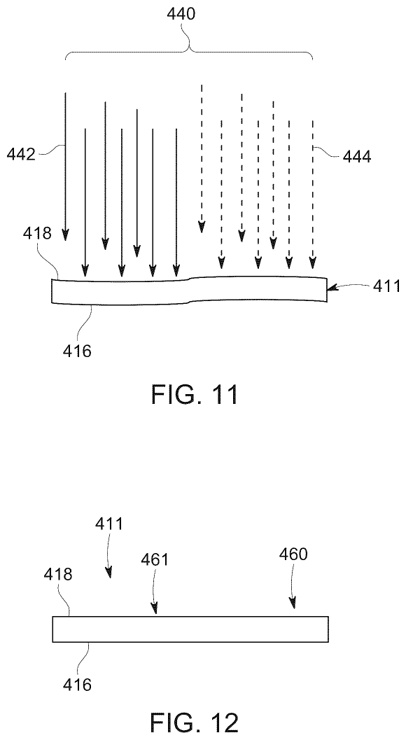

As shown in FIG. 11, an ion treatment 440 may then be performed to deliver ions to the back side 418 of the substate 411, wherein the ion treatment 440 may include one or more ion implants (e.g., scanned spot beam or ribbon beam implant), which may impact all of the substrate 411, but which may be delivered with a different dose and/or implant energy to different areas of the substrate 411 based on the results of the metrology scan and known parameters of the substrate 411 (e.g., original substrate thickness, target thickness of the substrate following a thinning process, etc.). For example, first ions 442 may be directed to the first section 460 with a first dose and a first ion implant energy, while second ions 444 may be directed to the second section 461 with a second dose and a second ion implant energy.

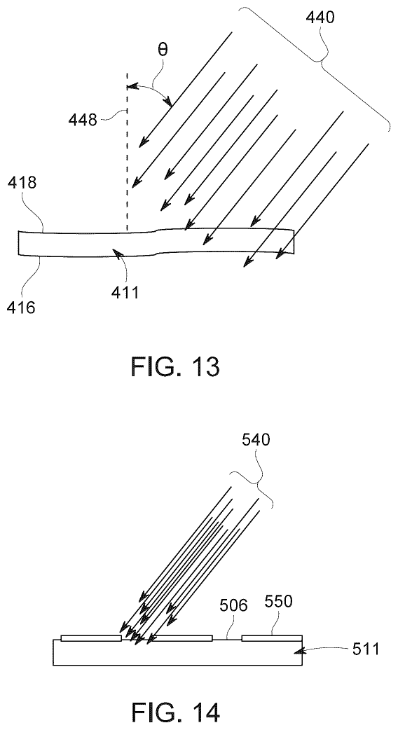

Furthermore, the species of the first ions 442 and the second ions 444 of the ions treatment 440 may be the same or different. For example, the ion treatment 440 may include one or more neutral ion species, such as silicon, argon, nitrogen, germanium, or carbon, wherein the first and/or second ions 442, 444 are directed to the substrate 411 vertically (as shown in FIG. 11) or at a non-zero angle θ relative to a perpendicular 448 extending from the substrate 411, as shown in FIG. 13. Having the first ions 442 and the second ions 444 directed to the substrate 411 with different doses, energies, species, temperatures, etc., allows for a variable depth and gradient of ion implant and, ultimately, a substrate 411 having altered or reduced wafer and die bow/warp, as shown in FIG. 12.

In still other embodiments, ions of the ion treatment 440 may be directed to the substrate 411 using a channeling implant to further modulate strains. For example, ions may be directed at a non-zero angle, e.g., between 1-89° relative to the perpendicular 448 to enable a deeper implant penetration without causing significant damage to the crystal structure of Silicon or Silicon carbide. When the substrate 411 is SiC, channeling occurs when the direction of implantation is within about 2° of a crystallographic axis of the silicon carbide crystal. In one example, channeling is particularly effective for SiC when the ion implantation has 0 deg tilt and where ion beam is normal to the incident substrate along the <0001>axis of 4H-SiC(100) and 6H-SiC(0001) wafers. Channeling may also be dependent on the wafer cut angle.

FIG. 14 demonstrates another example of an angled ion treatment 540 directed to a substrate 511 having one or more features 550 formed on a surface 506 thereof. The features 550 may represent a plurality of layers, devices, or semiconductor dies (chips), fabricated within or atop surface regions of the substrate 511, as known in the art. While shown as discrete components, the features 550 may also be formed generally in continuous fashion across the surface of the surface 506. During fabrication of the features 550, one layer or a plurality of layers may be deposited on the surface 506, where at least one layer may exhibit an intrinsic stress. As more layers are deposited and subsequently patterned, etched, and otherwise processed, for example, the intrinsic stress within the layers may tend to increase, particularly at higher-stress corners of the features 550, resulting in a distortion or curvature of the substrate 511 at an interface between the features 550 and the surface 506.

To mitigate this stress, the substrate 511 may be scanned and analyzed, as described above, and the tailored ion angled ion treatment 540 based on the results of that metrology and analysis may be directed to the substrate 511.

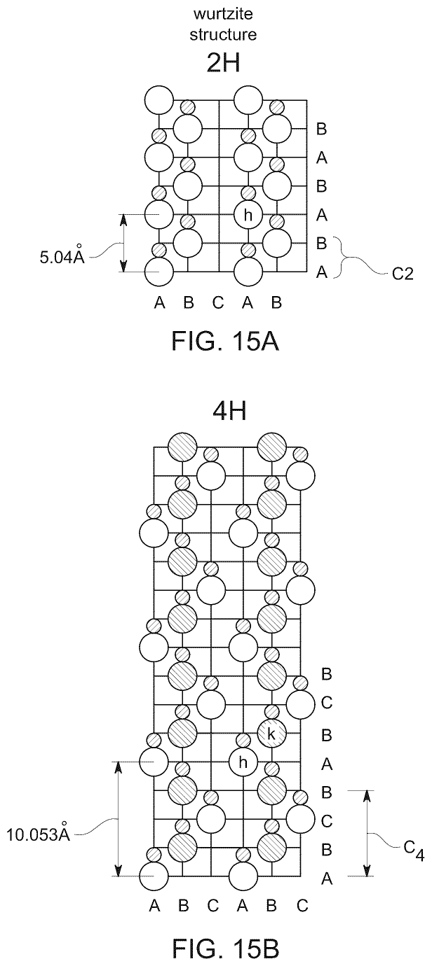

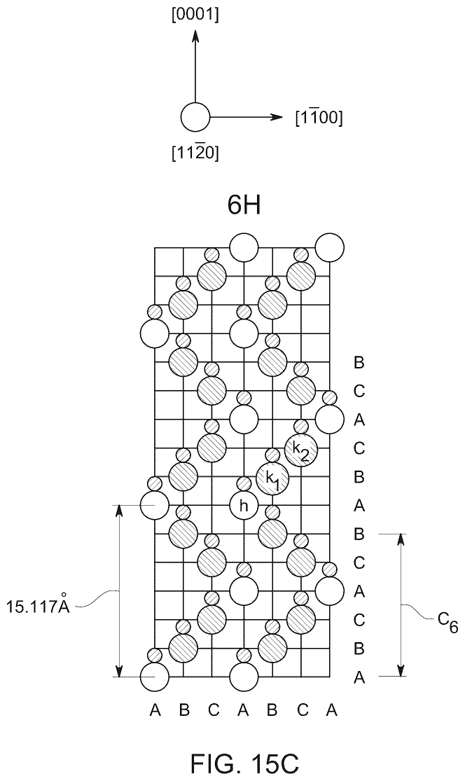

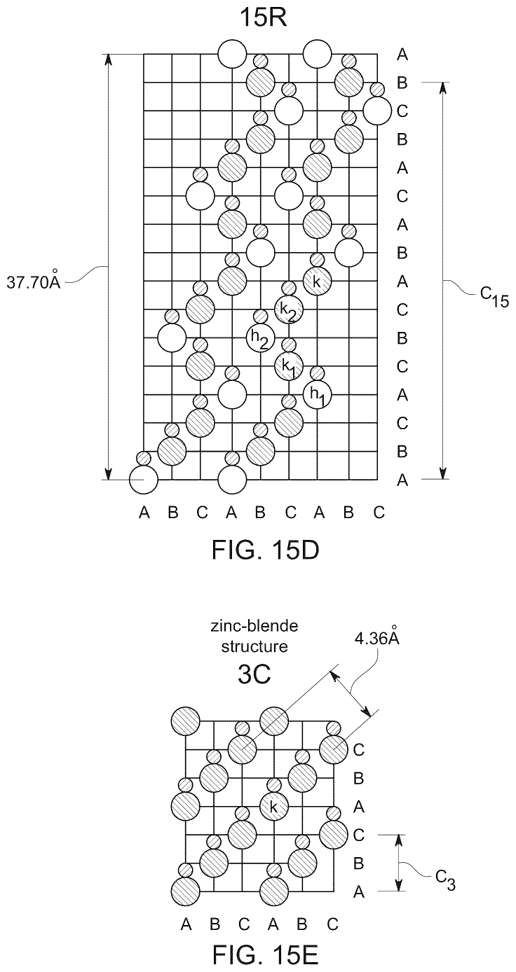

FIGS. 15A-15E demonstrate stacking sequences for different SiC polytypes in the plane of an example SiC substrate, such as substrates 411 and 511. The hexagonal SiC crystallographic structure allows for stronger channeling. Channeling for SiC ion implantation is particularly effective at 0 deg tilt where ion beam is normal to the incident substrate along the <0001> axis of 4H-SiC(100) and 6H-SiC(0001) wafers. Channeling will also dependent on the wafer cut angle.

As used herein, “depositing” and/or “deposited” may include any now known or later developed techniques appropriate for the material to be deposited including yet not limited to, for example: chemical vapor deposition (CVD), low-pressure CVD (LPCVD), and plasma-enhanced CVD (PECVD). Additional techniques may include semi-atmosphere CVD (SACVD) and high density plasma CVD (HDPCVD), rapid thermal CVD (RTCVD), ultra-high vacuum CVD (UHVCVD), limited reaction processing CVD (LRPCVD), metal-organic CVD (MOCVD), and sputtering deposition. Additional techniques may include ion beam deposition, electron beam deposition, laser assisted deposition, thermal oxidation, thermal nitridation, spin-on methods, physical vapor deposition (PVD), atomic layer deposition (ALD), chemical oxidation, molecular beam epitaxy (MBE), plating, thermal evaporation, or electron-beam evaporation.

For the sake of convenience and clarity, terms such as “top,” “bottom,” “upper,” “lower,” “vertical,” “horizontal,” “lateral,” and “longitudinal” will be understood as describing the relative placement and orientation of components and their constituent parts as appearing in the figures. The terminology will include the words specifically mentioned, derivatives thereof, and words of similar import.

As used herein, an element or operation recited in the singular and proceeded with the word “a” or “an” is to be understood as including plural elements or operations, until such exclusion is explicitly recited. Furthermore, references to “one embodiment” of the present disclosure are not intended as limiting. Additional embodiments may also incorporating the recited features.

Furthermore, the terms “substantial” or “substantially,” as well as the terms “approximate” or “approximately,” can be used interchangeably in some embodiments, and can be described using any relative measures acceptable by one of ordinary skill in the art. For example, these terms can serve as a comparison to a reference parameter, to indicate a deviation capable of providing the intended function. Although non-limiting, the deviation from the reference parameter can be, for example, in an amount of less than 1%, less than 3%, less than 5%, less than 10%, less than 15%, less than 20%, and so on.

Still furthermore, one of ordinary skill will understand when an element such as a layer, region, or substrate is referred to as being formed on, deposited on, or disposed “on,” “over” or “atop” another element, the element can be directly on the other element or intervening elements may also be present. In contrast, when an element is referred to as being “directly on,” “directly over” or “directly atop” another element, no intervening elements are present.

The foregoing discussion has been presented for purposes of illustration and description and is not intended to limit the disclosure to the form or forms disclosed herein. For example, various features of the disclosure may be grouped together in one or more aspects, embodiments, or configurations for the purpose of streamlining the disclosure. However, it should be understood that various features of the certain aspects, embodiments, or configurations of the disclosure may be combined in alternate aspects, embodiments, or configurations.

Moreover, the following claims are hereby incorporated into this Detailed Description by this reference, with each claim standing on its own as a separate embodiment of the present disclosure.

What is claimed is:

1. A method, comprising:
performing a metrology scan of a substrate, wherein the metrology scan determines a die warp or a die bow for each die of a plurality of dies across the substrate; and
directing first ions to the substrate, wherein the first ions are directed to a first die of the plurality of dies at a first dose and a first energy, and wherein the first dose and the first energy are determined based on the die warp or the die bow of the first die; and
directing second ions to the substrate, wherein the second ions are directed to a second die of the plurality of dies at a second dose and a second energy, and wherein the second dose and the second energy are determined based on the die warp or the die bow of the second die.

2. The method of claim 1, wherein the first dose and the first energy are further based on a first thickness of the first die and a species of the first ions, and wherein the second dose and the second energy are further based on a second thickness of the second die and a species of the second ions.

3. The method of claim 1, wherein the thickness of the first die is an estimated target thickness or a calculated thickness of the first die.

4. The method of claim 1, wherein the first ions and the second ions are neutral ion species.

5. The method of claim 1, wherein the substrate comprises a single crystal silicon or a silicon carbide.

6. The method of claim 1, wherein the first and second ions are delivered directly into an upper surface of the substrate at a non-zero angle relative to a perpendicular extending from the upper surface of the substrate.

7. The method of claim 1, wherein the first and second ions are directed to the substrate using a channeling implant.

8. The method of claim 1, further comprising thinning the substrate to partially expose a plurality of through silicon vias, wherein the first ions and second ions are directed to the substrate following the thinning of the substrate.

9. The method of claim 8, wherein thinning the substrate to expose the plurality of through silicon vias comprises performing an etch back process to the substrate.

10. The method of claim 9, further comprising:
depositing a dielectric over the substrate following the first and second ions being directed to the substrate; and
forming a conductive pad along each of the plurality of through silicon vias following deposition of the dielectric.

11. The method of claim 1, further comprising performing a second metrology scan of the substrate to determine an updated die warp or an updated die bow for each of the plurality of dies along the substrate.

12. An ion implanter, comprising:
an ion source for generating an ion beam;
an end station comprising a platen for supporting a substrate to be implanted by the ion beam; and
a main controller operatively coupled to the ion source, wherein the main controller is adapted to:
receive an output from a metrology scan of the substrate, wherein the metrology scan determines a die warp or a die bow for each die of a plurality of dies across the substrate;
direct first ions to a first die of the plurality of dies at a first dose and a first energy, wherein the first dose and the first energy are determined based on the die warp or the die bow of the first die; and
direct second ions to a second die of the plurality of dies at a second dose and a second energy, and wherein the second dose and the second energy are determined based on the die warp or the die bow of the second die.

13. The ion implanter of claim 12, wherein the first dose and the first energy are further based on a first thickness of the first die and a species of the first ions, and wherein the second dose and the second energy are further based on a second thickness of the second die and a species of the second ions.

14. The ion implanter of claim 12, wherein the main controller is adapted to perform the metrology scan of the substrate following a thinning of the substrate, wherein the thinning of the substrate exposes a plurality of through silicon vias in the substrate.

15. The ion implanter of claim 12, wherein the substrate comprises a single crystal silicon or a silicon carbide.

16. The ion implanter of claim 12, wherein the first and second ions are one or more neutral ion species.

17. The ion implanter of claim 12, wherein the first and second ions are directed to an exposed upper surface of the substrate at a non-zero angle relative to a perpendicular extending from the upper surface of the substrate.

18. The ion implanter of claim 12, wherein directing the first ions to the substrate comprises forming a stress neutralizing pattern on the first die, wherein the stress neutralizing pattern comprises at least one area of increased stiffness.

19. The ion implanter of claim 12, wherein the first ions or the second ions are directed to the substrate using a channeling implant.

20. A method of implanting wafer dies to mitigate die deformations, the method comprising:
receiving an output from a metrology scan of the substrate, wherein the metrology scan determines a die warp or a die bow for each die of a plurality of dies across the substrate;
directing first ions to a first die of the plurality of dies at a first dose and a first energy, wherein the first dose and the first energy are determined based on the following: the die warp or the die bow of the first die, a first thickness of the first die, and a species of the first ions; and
directing second ions to a second die of the plurality of dies at a second dose and a second energy, and wherein the second dose and the second energy are determined based on the following: the die warp or the die bow of the second die, a second thickness of the second die, and a species of the second ions.
